(19) United States
(12) Patent Application Publication
(10) Pub. No.: US 2021/0126155 A1
(43) Pub. Date: Apr. 29, 2021

(54) Method for Producing a Component and Optoelectronic Component

(71) Applicant: OSRAM OLED GMBH, Regensburg (DE)

(72) Inventors: Alexander Pfeuffer, Regensburg (DE); Britta Göötz, Regensburg (DE); Jens Müller, Regensburg (DE)

(73) Assignees: OSRAM OLED GmbH, Regensburg (DE); OSRAM OLED GmbH, Regensburg (DE)

(21) Appl. No.: 17/256,043

(22) PCT Filed: Jul. 29, 2019
(86) PCT No.: PCT/EP2019/070357

§ 371 Date: Dec. 24, 2020

(30) Foreign Application Priority Data
Aug. 2, 2018 (DE) 10 2018 118 808.0

(51) Int. Cl. H01L 33/00; H01L 27/15; H01L 33/22; H01L 33/50; H01L 33/08

(52) U.S. Cl. CPC H01L 33/005; H01L 27/156; H01L 33/22; H01L 2933/0041; H01L 33/08; H01L 33/507; H01L 33/504

(57) ABSTRACT

A method for producing a component and an optoelectronic component are disclosed. In an embodiment a method for producing a component includes providing an auxiliary carrier having a base body and a grid, providing a semiconductor body having an active zone for generating electromagnetic radiation, bonding the auxiliary carrier to the semiconductor body, wherein the grid is formed in the base body prior to the bonding and has a plurality of openings, and wherein after bonding, the base body is removed for exposing the grid and forming a converter layer by at least partially filling the openings of the grid, the converter layer for converting the electromagnetic radiation with respect to its peak wavelength.

This patent application is a national phase filing under section 371 of PCT/EP2019/070357, filed Jul. 29, 2019, which claims the priority of German patent application 102018118808.0, filed Aug. 2, 2018, each of which is incorporated herein by reference in its entirety.

### TECHNICAL FIELD

A method for producing a component, in particular a plurality of components, is specified. Furthermore, a component, in particular an optoelectronic component, is specified.

### BACKGROUND

By optical separation between adjacent regions of a converter layer, an optical contrast of a pixelated component, especially of a semiconductor chip, can be increased. For optical isolation, separation structures can be applied to the converter layer, for example by an electroplating process. However, this process is limited in the choice of materials by electroplating and in the dimensions by lithography. In order to prevent lateral wide-spreading of converted light, the converter layer can also be made as thin as possible. However, this has a negative influence on the efficiency of the converter layer.

### SUMMARY

Embodiments provide a component, in particular an optoelectronic component, which is particularly compact and has a particularly high optical contrast. Further embodiments provide a reliable and cost-efficient method for producing one or a plurality of components described here in particular.

A method for producing a component or a plurality of components, in particular of optoelectronic components, is specified. In particular, the component is a pixelated optoelectronic component or a pixelated light emitting semiconductor chip.

According to at least one embodiment of the method, an auxiliary carrier is provided. The auxiliary carrier has a base body. In particular, the auxiliary carrier has a grid which is preferably formed in the base body. The base body can have a plurality of trenches, wherein the grid is formed by filling the trenches with a grid material, preferably with a radiation-reflective material. The base body can be formed or consist of a semiconductor material, for example of silicon. Especially preferred is the base body made of monocrystalline silicon. Using an etching process, especially wet chemical etching, smooth and beveled flanks of the trenches can be formed. By filling the trenches with a grid material, the grid can have openings with beveled flanks. If the trenches are filled up with a grid material, the grid can have beveled separating walls. For example, the flanks or separating walls form an angle of between 5° and 60° to the vertical, for instance between 10° and 45° or between 10° and 30°.

The grid material or the radiation-reflective material can be electrically conductive or electrically insulating. In particular, the grid material is made of a metal such as aluminum. It is possible that the grid material is made of a non-reflective material. However, the grid material or the grid can have a radiation-reflective coating. For example, the grid material or the grid is silver-plated or coated with a thin layer of rhodium, silver and/or aluminum.

According to at least one embodiment of the method, the grid is formed by filling the trenches with a grid material, wherein the grid material is a radiation-reflective material. In particular, it is possible that the grid material is a non-reflecting material which is subsequently coated to be radiation-reflective, especially after the removal of the base body of the auxiliary carrier.

According to at least one embodiment of the method, a semiconductor body is provided. The semiconductor body is present in particular in the form of a semiconductor composite or of a semiconductor wafer. For example, the semiconductor body is based on GaN or on another III-V or II-VI compound semiconductor material. In particular, the semiconductor body has an active zone that is configured to generate electromagnetic radiation during operation of the component. The semiconductor body may have a first and a second semiconductor layer, wherein the active zone is arranged in particular in the vertical direction between the first semiconductor layer and the second semiconductor layer. The active zone is in particular a p-n junction zone. For example, during operation of the component, the active zone emits electromagnetic radiation in the visible spectral range, in the ultraviolet spectral range and/or in the infrared spectral range.

A vertical direction is a direction which is in particular perpendicular to a main extension surface of the component or of the active zone. A lateral direction is a direction which is in particular parallel to the main extension surface of the component or of the active zone. The vertical direction and the lateral direction are in particular orthogonal to each other.

According to at least one embodiment of the method, the grid has a plurality of openings. In the lateral directions, the openings of the grid can be completely surrounded by inner walls of the grid. The openings of the grid can be partially or completely filled by a material of the base body. It is possible that the auxiliary carrier has a separation layer which is placed on the grid and partially or completely covers the grid. Along the vertical direction, the grid can be located between the base body and the separation layer of the auxiliary carrier. The separation layer is especially formed to be electrically insulating. However, it is possible that the separation layer is electrically conductive. Preferably, the separation layer is formed to be radiation-transmissive, especially transparent.

According to at least one embodiment of the method, the auxiliary carrier is bonded, in particular mechanically connected to the semiconductor body. The grid has a plurality of openings. Before bonding the auxiliary carrier to the semiconductor body, the grid can be embedded in the base body such that the openings of the grid are at least partially filled by a material of the base body.

After bonding the auxiliary carrier to the semiconductor body, the grid is located for instance between the semiconductor body and the base body. The base body of the auxiliary carrier is especially faced away from the semiconductor body. In particular, the base body has an exposed surface which is faced away from the semiconductor body. After bonding the auxiliary carrier to the semiconductor body, the base body can be removed at least partially or completely for exposing the grid. At the exposed surface of the base body, the base body can be partially or completely removed by material removal, for example by a grinding process, and/or by an etching process for exposing the grid.

According to at least one embodiment of the method, a converter layer is formed such that the converter layer fills the openings of the grid at least partially or completely. Preferably, the converter layer is configured to convert the electromagnetic radiation generated by the active zone during operation of the component with respect to its peak wavelength. The converter layer may have a single phosphor or a single phosphor composition. Alternatively, the converter layer may contain a plurality of conversion regions with different phosphors or phosphor compositions. For example, the openings of the grid can be filled with different phosphors of the converter layer. It is possible that the conversion regions of the converter layer are each assigned to one of the openings of the grid. The conversion regions of the converter layer in the different openings of the grid can be spatially and/or optically separated from each other by the grid. This allows a particularly high contrast on a radiation-emitting surface of the component to be achieved.

In at least one embodiment of the method for producing a component or a plurality of components, an auxiliary carrier having a base body and a grid is provided. In addition, a semiconductor body having an active zone, which is configured to generate electromagnetic radiation, is provided. The auxiliary carrier is bonded to the semiconductor body, wherein prior to the bonding, the grid is formed in the base body and has a plurality of openings. After the bonding, the base body is removed at least partially or completely for exposing the grid. A converter layer is formed such that it at least partially or completely fills the openings of the grid. The converter layer is especially configured to convert the electromagnetic radiation generated by the active zone during operation of the component with respect to its peak wavelength.

In the absence of the semiconductor body and before being applied to the semiconductor body, the grid, which is used to increase the optical contrast of the component, such as the brightness or color contrast, is thus produced in the base body of the auxiliary carrier. Only after the grid has been applied to the semiconductor body, the base body of the auxiliary carrier is removed, thereby exposing the grid.

The grid is therefore not formed directly on the semiconductor body, but is applied to the semiconductor body in a prefabricated manner. In particular, the openings of the grid are filled with different luminescent materials or luminescent compositions of the converter layer. Before the converter layer is applied, the grid can be encapsulated against harmful environmental influences. Since the conversion regions of the converter layer are completely separated from each other by the openings of the grid, the openings of the grid can be filled with conversion materials of different degrees of conversion and/or different conversion colors. Preferably, the grid is made of a radiation-reflective material which in particular has a higher reflectivity than silicon. By suitable material selection the grid can be formed such that it has a reflectance of at least 60%, 70%, 80%, 90% or of at least 95% with respect to the converted radiation. A high optical contrast of the component can be achieved by optical separation of the conversion regions of the converter layer.

According to at least one embodiment of the method, a separation layer is arranged between the semiconductor body and the converter layer. The openings of the grid have bottom surfaces which are formed in particular by surfaces of the separation layer. The separation layer can be integral part of the auxiliary carrier or integral part of a main body, wherein in addition to the separation layer, the main body comprises the semiconductor body.

It is possible that the separation layer has a first partial layer that is assigned to the auxiliary carrier. For example, the first partial layer is adjacent to the grid, especially directly adjacent to the grid. The separation layer may have a second partial layer which is assigned to the main body. The second partial layer of the separation layer can be directly adjacent to the semiconductor body and/or directly adjacent to the first partial layer of the separation layer. For example, the separation layer is formed from an electrically insulating material, for example from an oxide material, for instance SixOy such as SiO₂, and/or from a nitride material, for instance SixNy such as Si₃N₄, or Nb₂O₅ or from a similar material. However, it is possible that the separation layer is electrically conductive. In particular, the separation layer is formed from a transparent electrically conductive material, for instance from a transparent electrically conductive oxide (TCO). The first partial layer and the second partial layer of the separation layer can be made from the same material or from different materials.

According to at least one embodiment of the method, the separation layer is formed between the semiconductor body and the converter layer, wherein the separation layer is removed at least in places after the auxiliary carrier is bonded to the semiconductor body, in particular for partially exposing the semiconductor body. The semiconductor body, in particular the first semiconductor layer of the semiconductor body can be roughened. The converter layer can be applied directly to the semiconductor body, in particular to the roughened semiconductor body.

According to at least one embodiment of the method, the base body is removed by using an etching process for exposing the grid. Prior to the etching process, the base body can be partially removed by material removal, for example by a grinding process. By exposing the grid, the separation layer, especially the first partial layer of the separation layer, can also be exposed. In particular, the material of the base body is selected such that it can be selectively removed with regard to the material of the separation layer. Preferably, the material of the separation layer is selected in view of the material of the base body such that the separation layer serves as an etch stop layer. It is also possible that the separation layer is removed partially or completely during or after the removal of the base body.

According to at least one embodiment of the method, trenches are formed in the auxiliary carrier. The grid is formed in particular by filling up the trenches. For example, the trenches are formed by structuring the base body. For example, the trenches are etched into the base body of the auxiliary carrier to form a negative mold. The trenches can then be filled with a radiation-reflective material, for example, with a liquid or low-melting material.

The radiation-reflective material can be a metal, such as Ag, Al, Ni, Pd or Pt, or an electrically insulating material with reflecting particles embedded therein. The vertical height of the grid is thus determined in particular by the depth of the trenches. The height of the grid can thus be precisely adjusted. After filling the trenches, the grid can be covered with a protective layer. The protective layer can be made of an electrically insulating material, especially of an anti-wetting material. In particular, the protective layer forms the separation layer or a partial layer of the separation layer. Before the auxiliary carrier is bonded to the semiconductor body or the main body, the auxiliary carrier may have an exposed surface which is formed in particular by a surface of the protective layer. In a plan view of the auxiliary carrier, the protective layer may partially or completely cover the grid. It is possible that the grid extends in places throughout the protective layer or throughout the first separation layer. In this case, the auxiliary carrier may have an exposed surface, especially a planar surface, which is formed in places by surfaces of the grid and in places by surfaces of the first separation layer.

According to at least one embodiment of the method, the auxiliary carrier is mechanically bonded to the semiconductor body by a direct bonding process. Prior to the bonding to the semiconductor body, the auxiliary carrier may have a planar exposed surface. Prior to the bonding to the auxiliary carrier, the semiconductor body may have a planar exposed surface. It is possible that the semiconductor body is part of a main body. In addition to the semiconductor body, the main body may have an electrically insulation layer, which in a plan view partially or completely covers the semiconductor body. For example, prior to the bonding to the auxiliary carrier, the main body has a planar exposed surface which is at least partially or completely formed by an exposed surface of the electrically insulation layer. Alternatively or in addition, it is possible for the main body to have a substrate on which the semiconductor body is situated. The substrate can be a growth substrate or different from a growth substrate on which the semiconductor body is grown, for instance epitaxially.

In a direct bonding process, in particular planar surfaces are brought into physical contact. The basis of the mechanical bond are mainly or exclusively hydrogen bonds and/or Van-der-Waals-interactions in the immediate vicinity of a common interface between the planar surfaces. In particular, the common interface is free of any bonding material, such as solder or adhesion promoter material. The common interface is in particular an overlapping surface between the previously exposed planar surfaces that is formed during the bonding process. The planar exposed surface/s has/have a roughness which is in particular 50 nm, 30 nm, 20 nm, 10 nm or 5 nm at most. In order to form covalent bonds between atoms or molecules on the surfaces being in physical contact, a thermal treatment is applied subsequently for achieving increased bond strength. Alternatively, it is conceivable that the auxiliary carrier is mechanically bonded to the semiconductor body by a connecting layer, such as an adhesive layer or a solder layer.

According to at least one embodiment of the method, the auxiliary carrier is mechanically connected to the main body comprising the semiconductor body. Preferably, the auxiliary carrier and the main body are mechanically and/or electrically connected to each other by a direct bonding process. For example, prior to direct bonding, the auxiliary carrier and the main body can each have an exposed, planar and exclusively electrically insulating surface. After the process of bonding the auxiliary carrier to the main body, a separation layer may be formed between the main body and the auxiliary carrier. After the bonding process, the separation layer can be removed at least in the areas of the openings of the grid.

In particular, the separation layer has a first partial layer belonging to the auxiliary carrier and a second partial layer belonging to the main body. For example, the exposed, planar and exclusively electrically insulating surface of the auxiliary carrier is formed by an exposed surface of the first partial layer. The exposed, planar and exclusively electrically insulating surface of the main body can be formed by an exposed surface of the second partial layer. In particular, no bonding agent or adhesion promoter material is used in a direct bonding process. A common interface between the auxiliary carrier and the main body is formed in particular by an overlapping surface between the exposed and planar surfaces of the main body and the auxiliary carrier.

According to at least one embodiment of the method, prior to the direct bonding process, the auxiliary carrier and/or the main body have/has an exposed, planar and exclusively electrically conductive surface. The separation layer or the partial layer of the separation layer, which is assigned to the auxiliary carrier, and/or the main body can be made of a metallic or of a transparent electrically conductive material.

According to at least one embodiment of the method, prior to the direct bonding process, the auxiliary carrier and the main body each have an exposed, planar and in places electrically insulating and in places electrically conductive surface. In particular, prior to the direct bonding process, both the main body and the auxiliary carrier each have an exposed and planar surface which is formed as a so-called hybrid surface. Such a hybrid surface has electrically insulating and electrically conductive regions being directly adjacent to each other.

The electrically conductive regions can be formed by surfaces of electrically conductive structures. The electrically insulating regions of the hybrid surface can be formed by surfaces of the first or second partial layer of the separation layer. Along the vertical direction, the electrically conductive structures can extend throughout the first partial layer or throughout the second partial layer. Alternatively, it is possible that the electrically conductive structures extend only into the first or second partial layer, wherein the electrically conductive structures have exposed surfaces that form the hybrid surface in places.

According to at least one embodiment of the method, the separation layer is transparent to the electromagnetic radiation generated during operation of the component. In particular, the separation layer comprising the first partial layer and/or the second partial layer is formed with respect to the material selection and/or with respect to the layer thickness such that at least 60%, 70%, 80%, 90% or at least 95% of the electromagnetic radiation generated by the active zone is transmitted throughout the separation layer.

In a direct bonding process, the separation layer can be directly or indirectly adjacent to the semiconductor body and the grid. In particular, there is no other bonding material or connecting layer situated between the semiconductor body and the grid. For example, the separation layer has a total vertical layer thickness which is, for example, between 50 nm and 50 μm inclusive, between 100 nm and 10 μm inclusive, between 100 nm and 5 μm inclusive, or between 100 nm and 1 μm inclusive. Compared to a process wherein the grid is adhered to the semiconductor body, for example by an additional connecting layer, the direct bond process allows the use of a separation layer having a significantly lower layer thickness than a conventional connecting layer, which usually has a higher absorption coefficient than the separation layer and counteracts the desired contrast effect and efficiency.

A component having a semiconductor body and a converter layer is specified, wherein the converter layer is arranged in openings of a grid. In particular, the component is an optoelectronic semiconductor chip, such as a pixelated light emitting diode (LED).

The method described above for producing a component or a plurality of components is particularly suitable for the production of a component described here. Thus, the features described in connection with the component can also be used for the method, and vice versa.

In at least one embodiment of the component, it has a semiconductor body, a grid, a converter layer and a separation layer. The semiconductor body has an active zone which is configured to generate electromagnetic radiation. The grid has a plurality of openings which are filled at least partially or completely by the converter layer. The converter layer is configured to convert the electromagnetic radiation generated by the active zone during operation of the component with respect to its peak wavelength. In particular, the separation layer is arranged at least in places between the semiconductor body and the converter layer. The separation layer is made preferably from an electrically insulating material or from a transparent electrically conductive material, for instance from a TCO material.

According to at least one embodiment of the component or of the method, the openings of the grid have bottom surfaces, which are preferably formed by surfaces of the separation layer. The bottom surfaces of the openings of the grid can be formed partially or completely by the surfaces of the separation layer. However, it is possible that the separation layer has structured regions, wherein the converter layer extends vertically through the separation layer, for instance up to the semiconductor body. Such structured regions are especially openings of the separation layer which are formed as inner radiation passage areas of the component.

In particular, the component is formed as an LED component having a plurality of individually controllable pixels. The component may have a contiguous semiconductor body having a plurality of individually controllable subregions. In particular, each of the subregions of the semiconductor body is assigned to one of the openings of the grid, and preferably vice versa. The subregions of the semiconductor body can be connected individually electrically, for example when trenches are formed between the subregions of the semiconductor body and/or when for instance a structured contact layer for individual contacting of the subregions of the semiconductor body is formed on the semiconductor body.

According to at least one embodiment of the component or of the method, the component has a structured contact layer. The structured contact layer has a plurality of spatially separated partial layers. The spatially separated partial layers are especially formed for local electrical contacting of different subregions of the semiconductor body. The separated partial layers of the contact layer can be electrically contacted independently from each other. For example, each of the partial layers of the contact layer is assigned to a single subregion of the semiconductor body, and vice versa.

According to at least one embodiment of the component or of the method, the semiconductor body has a first semiconductor layer facing the converter layer and a second semiconductor layer facing away from the converter layer. The active zone is located in particular between the first semiconductor layer and the second semiconductor layer. For example, the first semiconductor layer is contiguous. The second semiconductor layer and/or the active zone can be contiguous.

The structured contact layer is especially configured for the electrical contacting of the second semiconductor layer. For example, the structured contact layer is arranged directly or indirectly on the second semiconductor layer. Due to the comparatively lower transverse conductivity of the second semiconductor layer, which is for instance a p-type semiconductor layer, regions of the second semiconductor layer that overlap with the structured contact layer in a plan view can be electrically activated essentially independently from each other. Due to the structured contact layer, certain subregions of the semiconductor body can be specifically electrically contacted.

According to at least one embodiment of the component or of the method, the component has an internal structure. The internal structure extends in particular throughout the second semiconductor layer and the active zone. It is possible that the internal structure extends only into the first semiconductor layer or throughout the first semiconductor layer. The internal structure can be electrically insulating.

According to at least one embodiment of the component or of the method, the internal structure has at least one through-via or several through-vias for the electrical contacting of the first semiconductor layer. For example, the internal structure has an insulation layer which laterally surrounds the through-via at least in places so that the through-via is electrically insulated by the insulation layer from the second semiconductor layer and from the active zone. It is possible that the internal structure has a plurality of such insulation layers, each of which laterally surrounds one of the through-vias.

The through-via and its associated insulation layer can be spaced from the further through-vias and further insulation layers. However, it is possible that the insulation layers form a common coherent insulation structure. The common insulation structure can divide the semiconductor body, in particular the second semiconductor layer and the active zone and/or the first semiconductor layer of the semiconductor body, into a plurality of subregions, wherein the subregions of the semiconductor body can be individually electrically contacted. The through-vias can be formed as local openings extending throughout the insulation structure. Alternatively, it is possible that the through-vias form a common contiguous through-via structure that extends throughout the insulation structure.

According to at least one embodiment of the component or of the method, the internal structure is formed to be contiguous such that the second semiconductor layer and the active zone are singulated by the internal structure into a plurality of individually contactable subregions of the semiconductor body. The respective subregions can be completely surrounded by the internal structure in the lateral directions. The first semiconductor layer of the semiconductor body can still be contiguous. Alternatively, it is possible that the first semiconductor layer is also singulated by the internal structure into a plurality of individual subregions. If the semiconductor body is singulated into a plurality of individually contactable subregions, the semiconductor body can—in this sense—have a plurality of trenches, which are filled up in particular by the internal structure.

According to at least one embodiment of the component or of the method, the component has a terminal structure. The terminal structure is located for instance between the grid and the semiconductor body. For example, the terminal structure is configured for electrically contacting the semiconductor body, in particular for electrically contacting the first semiconductor layer of the semiconductor body. Preferably, the terminal structure is electrically conductive. The terminal structure can be formed as part of the main body. Prior to the bonding of the auxiliary carrier to the main body, the terminal structure is in particular not electrically or mechanically connected to the grid.

The auxiliary carrier may have a first partial layer of the separation layer, wherein the grid extends throughout the first partial layer. The auxiliary carrier may have an exposed, in particular planar surface formed by surfaces of the grid and of the first partial layer. The main body may have a second partial layer of the separation layer, wherein the terminal structure extends throughout the second partial layer or into the second partial layer. Before being connected to the auxiliary carrier, the main body may have an exposed, in particular planar surface, which is formed by surfaces of the terminal structure and of the second partial layer. The exposed surfaces of the auxiliary carrier and of the main body are formed especially as hybrid surfaces. The auxiliary carrier and the main body can be electrically and mechanically connected to each other at the hybrid surfaces. Via the grid, the semiconductor body, in particular the first semiconductor layer of the semiconductor body, can be electrically contacted externally.

According to at least one embodiment of the component or of the method, the terminal structure is directly adjacent to the grid. The terminal structure may also directly adjoin the semiconductor body, in particular the first semiconductor layer of the semiconductor body. In particular, the junction structure extends along the vertical direction from the grid into the semiconductor body. It is possible that the terminal structure extends throughout the second partial layer of the separation layer to the semiconductor body or into the semiconductor body, in particular into the first semiconductor layer of the semiconductor body. The terminal structure is especially configured for electrical contacting of the first semiconductor layer of the semiconductor body. For example, the terminal structure is directly, electrically conductively connected to the first semiconductor layer.

According to at least one embodiment of the component or of the method, the component has a transparent encapsulation layer. The encapsulation layer is arranged in particular on surfaces of the grid and/or of the converter layer facing away from the semiconductor body or at least partially between the converter layer and the semiconductor body. In particular, the encapsulation layer may be directly adjacent to the grid, the converter layer and/or the separation layer.

### BRIEF DESCRIPTION OF THE DRAWINGS

Further preferred embodiments and further developments of the component and of the method for producing the component or a plurality of components are provided by the exemplary embodiments explained below in conjunction with FIGS. 1A to 4B.

FIGS. 1A, 1B, 1C, 1D, 1E and 1F show schematic representations of different method steps of a method for producing one component or a plurality of components;

FIGS. 2A, 2B, 2C, 2D, 2E and 2F show further schematic representations of different method steps of a method for producing a component or a plurality of components in sectional views;

FIGS. 3A, 3B, 3C and 3D show further schematic representations of various method steps of a method for producing one component or a plurality of components;

FIGS. 4A and 4B show schematic representations of some exemplary embodiments for a component in schematic sectional views; and

FIGS. 5A and 5B show schematic representations of some exemplary embodiments for a component in schematic sectional views.

Identical, equivalent or equivalently acting elements are indicated with the same reference numerals in the figures. The figures are schematic illustrations and thus not necessarily true to scale. Comparatively small elements and particularly layer thicknesses can rather be illustrated exaggeratedly large for the purpose of better clarification.

### DETAILED DESCRIPTION OF ILLUSTRATIVE EMBODIMENTS

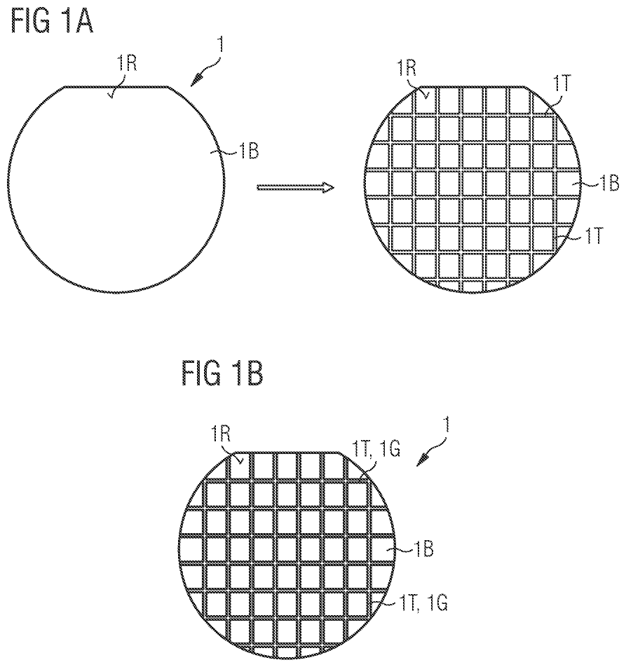

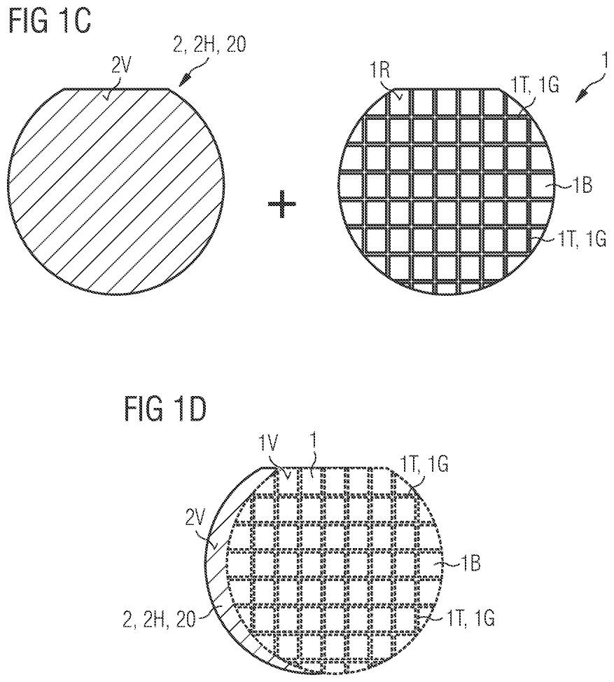

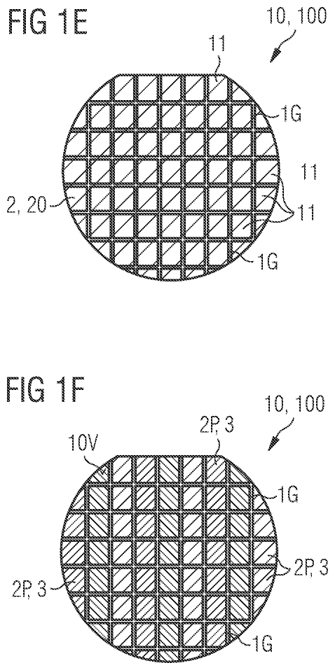

As shown in FIG. 1A, an auxiliary carrier 1 is provided. The auxiliary carrier 1 has a base body 1B. In particular, the base body 1B is made of a semiconductor material. For example, the base body 1B is made of or consists of silicon. The base body 1B has an exposed surface 1R which in particular forms a rear side 1R of the auxiliary carrier 1. On the exposed surface 1R, trenches 1T are formed into the base body 1B. The trenches 1T are in particular recesses on the rear side 1R of the auxiliary carrier 1. The trenches 1T extend in particular only into the base body 1B and not throughout the base body 1B.

The auxiliary carrier 1 can have a plurality of first trenches 1T running parallel to one another and a plurality of second trenches 1T running parallel to one another, wherein the first trenches 1T and the second trenches 1T are perpendicular to one another. The trenches can form openings that are filled by remaining material of the base body 1B. The trenches 1T form for instance a negative mold on the rear side 1R of the base body 1B. The negative mold has the shape of a grid, which can be formed in particular by filling the trenches 1T (FIG. 1B).

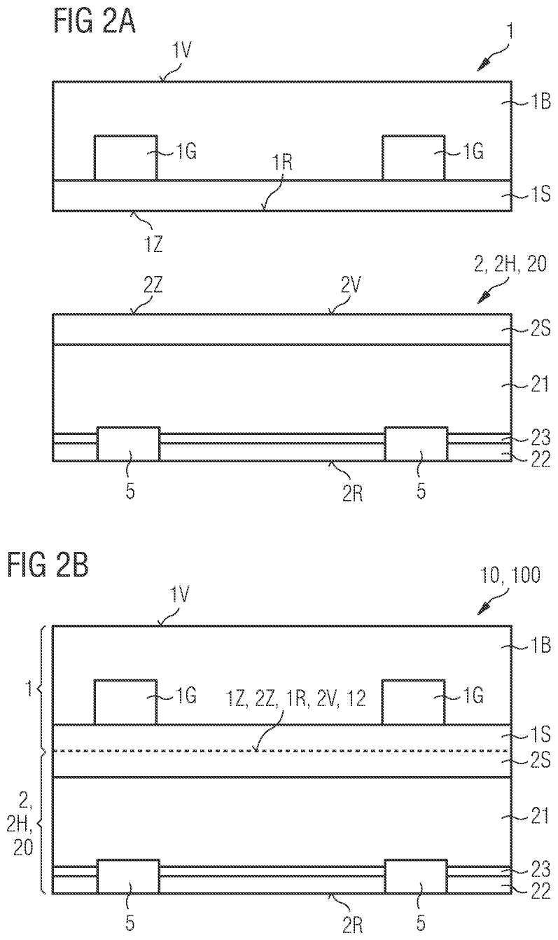

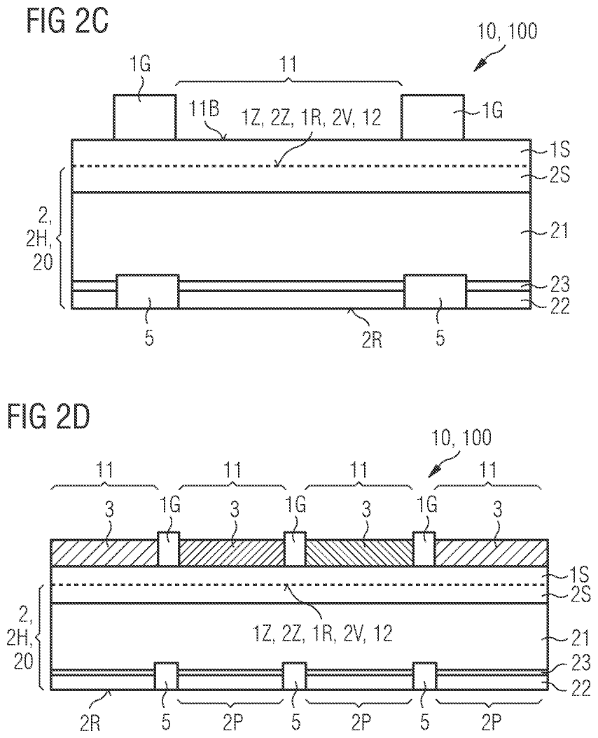

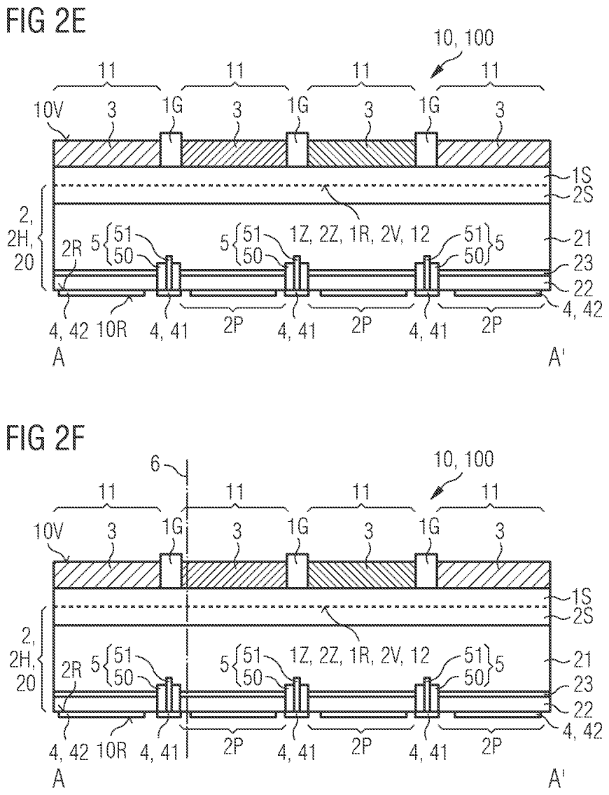

According to FIG. 1B, the grid 1G can be formed by filling the 1T trenches, in particular with a radiation-reflective material. The radiation-reflective material can be a metal, such as aluminum or silver. The radiation-reflective material can thus be electrically conductive. Alternatively, it is possible that the radiation-reflective material has a matrix material, especially an electrically insulating matrix material, wherein radiation-reflective particles are embedded therein. The radiation-reflective particles are for example titanium oxide particles. For forming the grid 1G, the 1T trenches can be partially or completely filled with the radiation-reflective material. The grid 1G can then be covered with a protective layer 1S (FIG. 2A). In particular, the protective layer 1S is made of an electrically insulating material that is preferably transparent to radiation. The auxiliary carrier 1 is formed especially as a carrier wafer.

According to FIG. 1C, a semiconductor wafer 20 is provided. In particular, the semiconductor wafer 20 is a semiconductor composite 20 that can be separated into a plurality of semiconductor bodies 2 or main bodies 2H. The semiconductor wafer 20 thus has at least one semiconductor body 2 or one main body 2H. The semiconductor body 2 is in particular formed as part of a main body 2H of the component 10 to be produced. In addition to the semiconductor body 2H, the main body 2H can have 2 further layers of the component 10, such as a contact layer for the electrical contacting of the semiconductor body 2 or an electrically insulating partial layer 2S or protective layer 2S arranged on the semiconductor body 2 (FIG. 2A).

According to FIGS. 1C and 1D, the auxiliary carrier 1 and the semiconductor body 2 or the main body 2H are mechanically bonded to each other to form a component composite 100. In particular, the connection of the auxiliary carrier 1 with the semiconductor body 2 or the main body 2H is carried out by a direct bonding process. Preferably, the auxiliary carrier 1 has an exposed, especially planar rear side 1R. The semiconductor wafer 20 or the main body 2H preferably has an exposed, especially planar front side 2V. The auxiliary carrier 1 and the semiconductor wafer 20 are preferably brought together such that the front side 2V of the semiconductor wafer 20 faces the rear side 1R of the auxiliary carrier 1. In FIG. 1D, the auxiliary carrier 1 has a front side 1V which is formed in particular by an exposed surface of the base body 1B of the auxiliary carrier 1. Along the vertical direction, the grid 1G is thus located between the base body 1B of auxiliary carrier 1 and the semiconductor body 2 of semiconductor wafer 20. In a plan view of the front side 1V, the grid 1G can be completely covered by the base body 1B.

According to FIG. 1E, the grid 1G of auxiliary carrier 1 is exposed. To expose grid 1G, the base body 1B is partially or completely removed. For example, a material of the base body 1B is removed until the grid 1G is exposed. For example, the base body 1B is first ground down and then etched away. In this way, only the desired grid material of the grid 1G remains on the semiconductor body 2 or on the semiconductor wafer 20. If necessary, the grid 1G can be covered by a further protective layer. A coating process such as an ALD (Atomic Layer Deposition) process is particularly suitable for this purpose.

According to FIG. 1E, the grid 1G has a plurality of openings 11. In particular, each opening 11 has the shape of a cavity which is completely surrounded in lateral directions by the inner walls of the grid 1G. The openings 11 are configured in particular to receive converter materials. In particular, the openings 11 are spatially separated from each other by the inner walls of the grid 1G.

According to FIG. 1F, the cavities n can be partially or completely filled with a converter layer 3. In the different openings 11 of the grid 1G, the converter layer 3 can have the same phosphors or different phosphors. The converter layer 3 has a surface which faces away from the semiconductor body 2 and in particular forms a front side 10V of the component 10 or of the component composite 100. Prior to or after the application of the converter layer 3, the component composite 100 can be separated into a plurality of individual components 10. In particular, the component composite 100 is separated into a plurality of components 10 such that the components 10 each have a semiconductor body 2 and a plurality of openings 11 of the grid 1G. Each opening 11 of the grid 1G can be assigned to a single subregion 2P of the semiconductor body 2. Conversely, each subregion 2P of the semiconductor body 2 can be assigned to a single opening 11 of the grid 1G. Preferably, the component 10 is formed such that the subregions 2P of the semiconductor body 2 can be individually electrically contactable, i.e. essentially independently of each other.

The exemplary embodiment for an auxiliary carrier 1 shown in FIG. 2A essentially corresponds to the exemplary embodiment for an auxiliary carrier 1 shown in FIG. 1B. In contrast, the separation layer or the protective layer 1S of the auxiliary carrier 1 is shown schematically. The separation layer 1S can cover, in particular completely cover the trenches 1T or the grid 1G. In particular, the separation layer 1S is made of an electrically insulating material or of a transparent electrically conductive material. For example, with regard to its material selection and/or layer thickness, the separation layer 1S is formed such that the separation layer 1S is transparent to radiation. The separation layer 1S of the auxiliary carrier 1 has an exposed surface 1Z of the auxiliary carrier 1, wherein the exposed surface 1Z forms a rear side 1R of the auxiliary carrier. For a direct bonding process, the surface 1Z of auxiliary carrier 1 is especially formed to be planar.

FIG. 2A schematically shows a section of the semiconductor body 2, the semiconductor wafer 20 or the main body 2H. The semiconductor body 2 has a first semiconductor layer 21, a second semiconductor layer 22 and an active zone 23 located between the semiconductor layers 21 and 22. A separation layer or a protective layer 2S of the main body 2H is arranged on the first semiconductor layer 21. The separation layer 2S of the main body 2H has an exposed surface 2Z which in particular forms a front side 2V of the main body 2H or of the semiconductor wafer 20. In particular, the exposed surface 2Z is planar. The separation layer 1S of the auxiliary carrier 1 and of the separation layer 2S of the main body 2H can be made of the same material or of different, preferably electrically insulating materials. In particular, the separation layer 2S of the main body 2H is formed to be radiation-transmissive, analogous to the separation layer 1S of the auxiliary carrier 1.

The active zone 23 is configured to generate electromagnetic radiation during operation of the component 10. The first semiconductor layer 21 and the second semiconductor layer 22 are especially formed to be n-type or p-type, respectively, or vice versa. In particular, the second semiconductor layer 22 has an exposed surface 2R which forms for instance a rear side 2R of the semiconductor body 2 or of the main body 2H.

The main body 2H has an internal structure 5. The internal structure 5 extends in particular from the rear side 2R of the semiconductor body 2 throughout the second semiconductor layer 22 and the active zone 23 into the first semiconductor layer 21. It is possible that the internal structure 5 is formed in a contiguous manner and divides the semiconductor body 2, at least in the regions of the active zone 23 and the second semiconductor layer 22, into a plurality of spatially separated and thus individually electrically contactable subregions 2P of the semiconductor body 2. Alternatively, it is possible that the internal structure has 5 local, spatially separated integral parts which extend throughout the second semiconductor layer 22 and the active zone 23. In this case, the local integral parts of the internal structures 5 may be completely surrounded in the lateral directions by the for instance contiguous second semiconductor layer and/or by the for instance contiguous active zone 23.

According to FIG. 2B, the auxiliary carrier 1 and the main body 2H are joined together such that the front side 2V of the main body 2 and the rear side 1R of the auxiliary carrier 1 face each other. In particular, the auxiliary carrier 1 and the main body 2H are mechanically bonded together by a direct bonding process. In a direct bonding process, a common interface 12 is formed between the auxiliary carrier 1 and the main body 2H, wherein the common interface 12 is formed exclusively by the rear side 1R of the auxiliary carrier 1 and the front side 2V of the main body 2H or by the planar surfaces 1Z and 2Z. In particular, the common interface 12 is free of a bonding agent, e.g. free of an adhesive material or of a solder material. In other words, the common interface 12 is in particular free of a bonding agent material which is different from a material of the separation layer 1S of the auxiliary carrier 1 and/or from a material of the separation layer 2S of the main body 2H.

After joining, the auxiliary carrier 1 and the main body 2H or the semiconductor composite 20 form a component composite 100. The component composite 100 can be separated into a plurality of components 10 in a subsequent method step.

The grid 1G is exposed as shown in FIG. 2C. For exposing the grid 1G, the base body 1B of the auxiliary carrier 1 is partially or completely removed. An etching process can be used to completely remove the base body 1B. The separation layer 1S and/or the separation layer 2S can serve as an etch stop layer. Preferably, the grid 1G is formed to be contiguous. The grid 1G can have a plurality of openings 11. In particular, the opening 11 has a bottom surface 11B which is preferably formed by a surface of the separation layer 1S or 2S. The opening 11 has the shape of a cavity, with the cavity being limited in the lateral directions by inner walls of the grid 1G. The grid 1G may have a plurality of such openings 11.

According to FIG. 2D, the openings 11 are filled with a converter layer 3. The converter layer 3 can partially or completely fill the openings 11. It is possible that the converter layer 3 has the same phosphor composition or different phosphor compositions in the different openings 11. Thus, the converter layer 3 may have a plurality of spatially separated conversion regions located in the different openings 11 of the grid 1G. The grid 1G thus serves as an optical separation between the different conversion regions of the converter layer 3. The conversion regions preferably have different phosphor compositions in the different openings 11. For example, the conversion regions are for converting light of blue or ultraviolet wavelengths into light of green, yellow or red wavelengths.

According to FIG. 2D, the semiconductor body 2 can have a plurality of subregions 2P. In a plan view of the semiconductor body 2, each of the conversion regions of the converter layer 3 can cover one of the subregions 2P. It is possible that each of the conversion regions of the converter layer 3 is assigned to exactly one of the subregions 2P of the semiconductor body 2, and preferably vice versa. In particular, the subregions 2P of the semiconductor body 2 are individually electrically contactable. In the regions of the second semiconductor layer 22 and the active zone 23, the subregions 2P of the semiconductor body 2 can be spatially spaced from each other or be contiguous. If the subregions 2P of the semiconductor body 2 are spatially spaced from each other in the lateral directions, the internal structure 5 can have similar shapes to the grid 1G. The grid 1G and the internal structure 5 can be configured to each other such that they have overlapping areas in a plan view which enclose the subregions 2P of the semiconductor body 2. However, it is possible that the subregions 2P continue to form a contiguous structure even in the presence of the internal structure 5.

The example shown in FIG. 2E for a component 10 or a component composite 100 is essentially the same as the example shown in FIG. 2D. In contrast, the electrical contacting of the semiconductor body 2 is shown in more detail. The component 10 has a contact layer 4 on the rear side 2R of the semiconductor body 2. Especially the contact layer 4 is structured.

According to FIG. 2E, the contact layer 4 has a plurality of first partial layers 41. The first partial layers 41 are especially configured for the electrical contacting of the first semiconductor layer 21. The first partial layers 41 of the contact layer 4 are assigned, for example, to the same first electrical polarity of component 10. The internal structure 5 has a plurality of through-vias 51 which extend along the vertical direction from the first partial layers 41 throughout the second semiconductor layer 22 and the active zone 23 into the first semiconductor layer 21. The internal structure 5 also has a plurality of insulation layers 50, each of which completely surrounds one of the through-vias 51 laterally so that the associated through-via 51 is electrically insulated from the active zone 23 and from the second semiconductor layer 22. Via the through-via or via the through-vias 51, the first semiconductor layer 21 is electrically connected to one or several partial layers 41.

The contact layer 4 has a plurality of second partial layers 42 on the rear side 2R of the semiconductor body 2. The second partial layers 42 of the contact layer 4 can be assigned, for example, to the same second electrical polarity of the component 10. The second partial layers 42 are spatially separated from each other on the rear side 2R and can be contacted individually electrically. In particular, the second partial layers 42 are each configured for electrically contacting a subregion 2P of the semiconductor body 2 or of the second semiconductor layer 22. Via the second partial layers 42 of the structured contact layer 4, the subregions 2P of the semiconductor body 2 can be contacted individually. Due to the comparatively lower transverse conductivity of the second semiconductor layer 22, the second semiconductor layer 22 or the active zone 23 can still form a contiguous common layer. Alternatively, it is possible that the insulation layers 50 of the internal structure 5 are formed coherently such that the subregions 2P are laterally separated from each other at least in the regions of the active zone 23 and the second semiconductor layer 22.

The exemplary embodiment of a component 10 or of a component composite 100 shown in FIG. 2F essentially corresponds to the exemplary embodiment shown in FIG. 2E. FIG. 2F shows that the component composite 100 can be separated into a plurality of components 10 along a separation line 6 or a plurality of separation lines 6. The separated component 10 can have a single opening 11 of the grid 1G or a plurality of openings 11 of the grid 1G. In particular, the component 10 is formed as a surface mountable component. In this case, the component 10 can only be contacted externally via its rear side 10R, since both the first partial layer 41 and the second partial layer 42 of the contact layer 4 are located on the rear side 10R of the component 10 and are accessible on the rear side 10R.

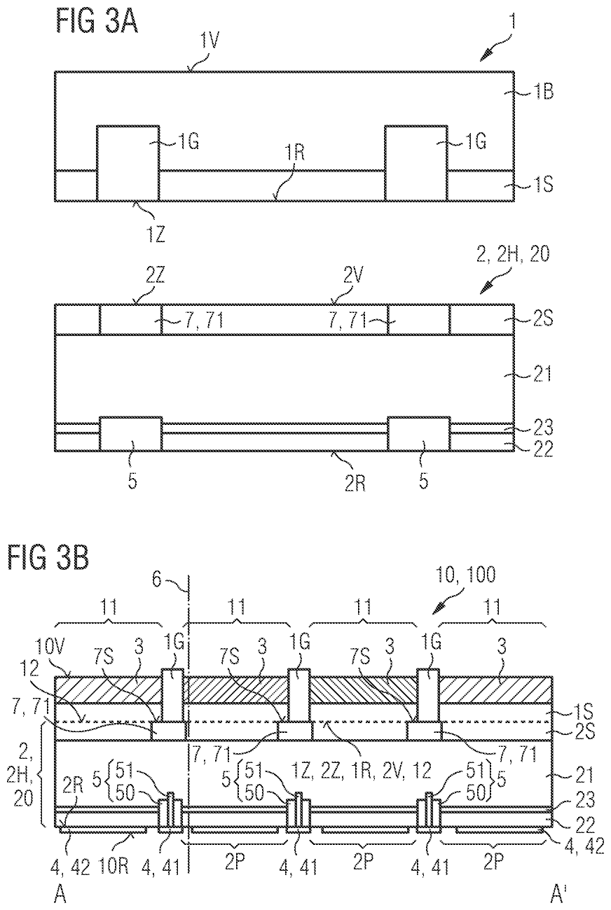

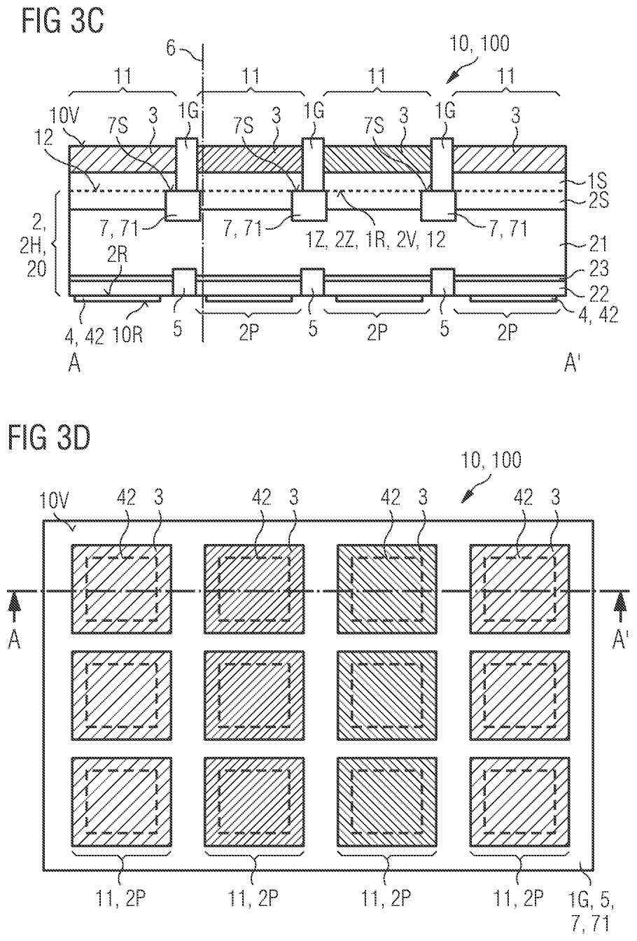

The exemplary embodiment for a method step shown in FIG. 3A essentially corresponds to the exemplary embodiment shown in FIG. 2A. In contrast, the grid 1G extends throughout the separation layer 1S of the auxiliary carrier 1. The exposed surface 1Z, which is particularly planar, is formed in places by surfaces of the separation layer 1S and in places by surfaces of the grid 1G. In this case, the grid 1G is preferably formed from an electrically conductive material. The exposed surface 1Z is thus especially formed as a hybrid surface which is electrically insulating in some places and electrically conductive in other places.

Similar to the auxiliary carrier 1, the main body 2H has an exposed, especially planar hybrid surface 2Z. The main body 2H or the semiconductor wafer 20 has a terminal structure 7, which is especially formed from an electrically conductive material. The terminal structure 7 is preferably configured for electrically contacting the first semiconductor layer 21. The terminal structure 7 has a plurality of through-contacts 71 which extend in particular throughout the separation layer 2S of the main body 2H. The exposed surface 2Z of the main body 2H is thus formed in places by surfaces of the separation layer 2S and in places by exposed surfaces of the terminal structure 7. It is possible that the terminal structure 7 and the grid 1G are made of the same material or of different materials. It is also possible that the terminal structure 7 is not formed for the electrical contacting of the semiconductor body 2 and is only formed for the optical separation between the conversion regions of the converter layer 3 or between the subregions 2P of the semiconductor body 2. In this case, the terminal structure 7 may be formed from an electrically insulating material.

The exemplary embodiment shown in FIG. 3B for a component 10 or for a component composite 100 essentially corresponds to the exemplary embodiment shown in FIG. 2F. In contrast to this, the component 10 or the component composite 100 has the grid 1G shown in FIG. 3A and the terminal structure 7 shown in FIG. 3A. Preferably, the auxiliary carrier 1 and the main body 2H are mechanically connected by a direct bonding process. Step transitions 7S or steps 7S can be formed at the common interface 12 between the terminal structure 7 and the grid 1G and/or between the separation layers 1S and 2S. In this case, the grid 1G and the terminal structure 7 can be directly adjacent to each other. Also the separation layer 1S of the auxiliary carrier 1 and the separation layer 2S of the main body 2 can be directly adjacent to each other.

The step 7S or the step transitions 7S can be regarded as characteristic features of a component 10 formed by a direct bonding process. The step transitions 7S at the common interface 12 are due in particular to the different geometries and/or sizes of the through-contacts 71 and the grid 1G or to the relative adjustment of the terminal structure 7 to the grid 1G. According to the exemplary embodiment shown in FIG. 2F, the common interface 12 is a pure insulator-insulator interface. In contrast, the interface 12 can be an insulator-insulator-, insulator-metal-, and metal-metal-interface as shown in FIG. 3B. The mechanical connection between the main body 2H and the separation layer 1S as well as the grid 1G is based in particular exclusively on hydrogen bridge compounds and/or on van der Waals interactions between the atoms at the common interface 12.

The first semiconductor layer 21 can be electrically contacted externally via the through-vias 51 and the first partial layers 41 or via the through-contacts 71 and the grid 1G. However, it is possible that the terminal structure 7 and the grid 1G do not contribute to the electrical contacting of the semiconductor body 2. Deviating from FIG. 3B, it is possible that the semiconductor body 2 is free of the through-vias 51. In this case the contact layer 4 is free of the first partial layers 41. Such an example for a component 10 or for a component composite 100 is shown schematically in FIG. 3C. In contrast to the exemplary embodiment in FIG. 3B, the through-contacts 71 extend into the first semiconductor layer 21 according to FIG. 3C. In the vertical direction, the terminal structure 7 is spaced from the internal structure 5.

Deviating from FIGS. 3B and 3C, it is possible that the through-contacts 71 extend up to the internal structure 5 into the first semiconductor layer 21 and into the second semiconductor layer 22. In deviation from FIGS. 3B and 3C, it is also possible that the separation layer 1S and/or the separation layer 2S is/are partially or completely removed after the bonding process. In particular, the first semiconductor layer 21 is exposed in places and can be roughened. The converter layer 3 can be applied directly onto the semiconductor body 2, for example directly onto the semiconductor layer 21. In all exemplary embodiments it is possible that only a part of the separation layer 1S and/or 2S in the region of the opening 11 or of the openings 11 of the grid 1G is removed. It is possible that the semiconductor body 2, especially the first semiconductor layer 21, is exposed in the area of the opening/s 11. In a subsequent method step, the opening/s 1 can be filled up with the converter layer 3.

FIG. 3D shows a component 10 or a component composite 100 in top view. The exemplary embodiment of a component 10 or of a composite 100 shown in FIG. 3D corresponds to the exemplary embodiments of a component 10 or of a component composite 100 along the intersection line AN shown in FIGS. 2E, 2F, 3B and 3C. As schematically shown in FIG. 3D, each of the conversion regions of the converter layer 3 or each of the subregions 2P of the semiconductor body 2 can be assigned to one of the subareas 42 of the contact layer 4, and in particular vice versa. In a plan view of the front side 10V of the component 10, a conversion region of the converter layer 3 or a subregion 2P of the semiconductor body 2 may cover, in particular completely cover, the associated partial layer 42 of the contact layer 4 on the rear side 10R of the component 10.

As shown schematically in FIG. 3D, each of the openings 11 of the grid 1G can be assigned to one of the partial layers 42 of the contact layer 4 and especially vice versa. Via the partial layers 42 of the contact layer 4, the subregions 2P of the semiconductor body 2 can be individually controlled, which allows the setting of any luminescent pattern on the front side 10V. For example, the semiconductor body 2 has at least 3, 9, 16, 32, 64 or at least 128 subregions 2P. The grid can have at least 3, 9, 16, 32, 64 or at least 128 openings 11.

As schematically shown in FIG. 3D, the grid 1G, the terminal structure 7 having the through-contacts 71 and/or the internal structure 50 having the insulation layers 50 can be formed contiguously. In a plan view of the front side 10V of the component 10, the conversion regions of the converter layer 3 and/or the subregions 2P of the semiconductor body 2 may be arranged in a matrix-like manner, i.e. in a plurality of rows and columns. In particular, the contiguous grid 1G, the contiguous terminal structure 7 and/or the contiguous internal structure 5 can realize an optical separation not only between the conversion regions of the converter layer 3, but also between the subregions 2P of the semiconductor body 2 and within the separation layers 1S and 2S, as a result of which an optimal optical contrast can be achieved.

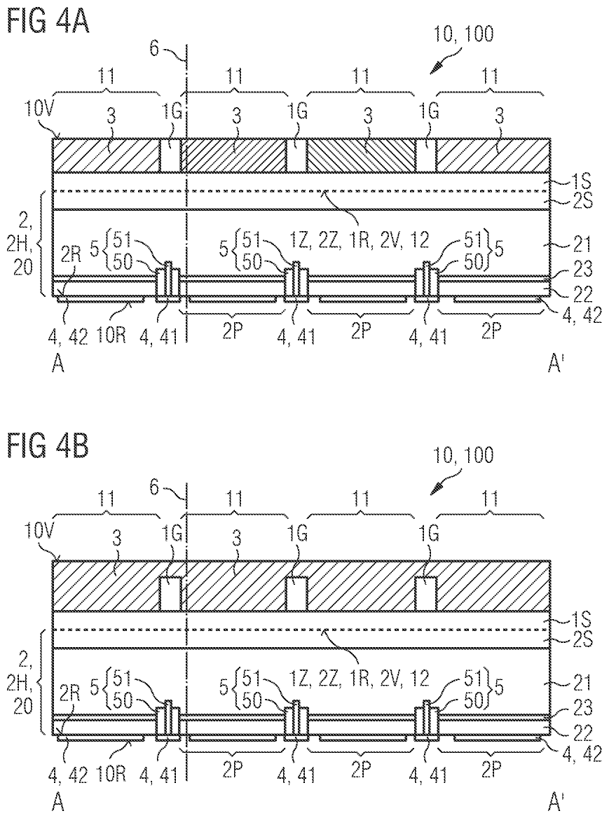

The exemplary embodiment of a component 10 or of a component composite 100 shown in FIG. 4A is essentially the same as the exemplary embodiment shown in FIG. 2F. In contrast, the openings 11 of the grid 1G are completely filled by the converter layer 3. In the vertical direction, the converter layer 3 and the grid 1G can be flush with each other.

The exemplary embodiment of a component 10 or of a component composite 100 shown in FIG. 4B essentially corresponds to the exemplary embodiment shown in FIG. 4A. In contrast, the converter layer 3 can fill the openings 11 such that the converter layer 3 protrudes vertically above the grid 1G. In contrast to FIG. 4A, wherein the subareas of converter layer 3 are spatially separated from each other by the grid 1G, as shown in FIG. 4B, the converter Layer 3 is formed to be contiguous.

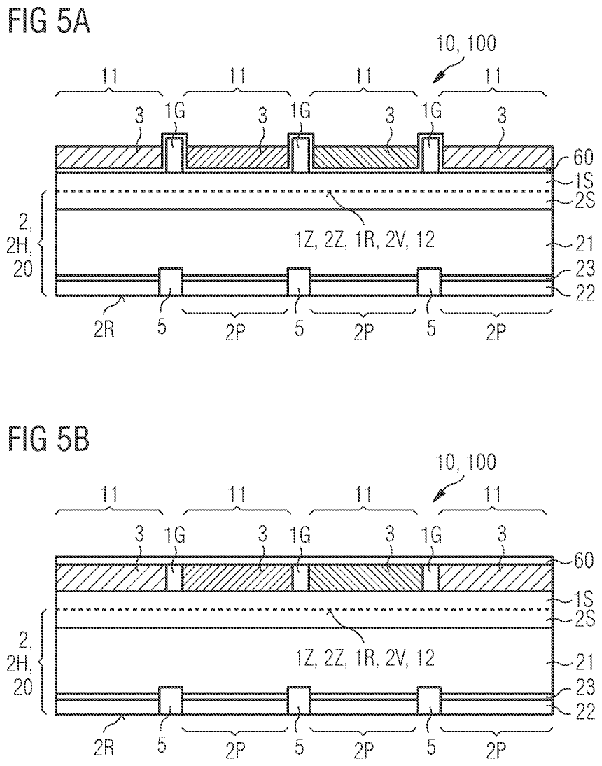

The exemplary embodiments shown in FIGS. 5A and 5B essentially correspond to the exemplary embodiment shown in FIG. 2D. In contrast, the component 10 has a transparent encapsulation layer 60.

According to FIG. 5A, the encapsulation layer 60 is at least partially located between the converter layer 3 and the semiconductor body 2, in particular between the converter layer 3 and the separation layer 1S or 2S. Except for a surface facing the separation layer 1S or 2S, the grid 1G may be completely encapsulated by the encapsulation layer 60. The bottom surfaces of the openings 11 can be formed by surfaces of the encapsulation layer 60.

As shown in FIG. 5B, the encapsulation layer 60 is located on surfaces of the grid 1G and of the converter layer 3 facing away from the semiconductor body 2. In a plan view, the encapsulation layer 60 can partially or completely cover the grid 1G and/or the converter layer 3.

The invention is not restricted to the exemplary embodiments by the description of the invention made with reference to exemplary embodiments. The invention rather comprises any novel feature and any combination of features, including in particular any combination of features in the claims, even if this feature or this combination is not itself explicitly indicated in the claims or exemplary embodiments.

1-20. (canceled)

21. A method for producing a component, the method comprising:
providing an auxiliary carrier having a base body and a grid;
providing a semiconductor body having an active zone for generating electromagnetic radiation;
bonding the auxiliary carrier to the semiconductor body, wherein the grid is formed in the base body prior to bonding and has a plurality of openings, and wherein after the bonding, the base body is removed for exposing the grid; and
forming a converter layer by at least partially filling the openings of the grid, the converter layer for converting the electromagnetic radiation with respect to its peak wavelength.

22. The method according to claim 21, further comprising:
disposing a separation layer between the semiconductor body and the converter layer, wherein bottom surfaces of the openings of the grid are formed at least in places by surfaces of the separation layer; and
removing the base body by an etching process thereby exposing the grid,
wherein the separation layer comprises a material which serves as an etch stop layer with respect to a material of the base body.

23. The method according to claim 21, further comprising:
forming a separation layer between the semiconductor body and the converter layer;
removing the separation layer at least in places after the auxiliary carrier has been bonded to the semiconductor body to partially expose the semiconductor body;
roughening the semiconductor body; and
applying the converter layer directly onto the roughened semiconductor body.

24. The method according to claim 21, further comprising:
forming trenches in the auxiliary carrier; and
forming the grid by filling the trenches with a grid material,
wherein the grid material is a radiation-reflective material, or
wherein the grid material is a non-reflective material that is subsequently coated to be radiation-reflective.

25. The method according to claim 21, wherein the auxiliary carrier is mechanically bonded to the semiconductor body by a direct bonding process.

26. The method according to claim 25, wherein the semiconductor body is part of a main body, wherein prior to directly bonding, the auxiliary carrier and the main body each has an exposed, planar and exclusively electrically insulating surface.

27. The method according to claim 25, wherein the semiconductor body is part of a main body, wherein prior to directly bonding, the auxiliary carrier and the main body each has an exposed, planar and exclusively electrically conductive surface.

28. The method according to claim 25, wherein the semiconductor body is part of a main body, wherein prior to directly bonding, the auxiliary carrier and the main body each has an exposed, planar surface which is electrically insulating in places and electrically conductive in places.

29. A component comprising:
a semiconductor body comprising an active zone configured to generate electromagnetic radiation;
a grid having a plurality of openings;
a converter layer configured to convert the electromagnetic radiation with respect to its peak wavelength; and
a separation layer at least partially arranged between the semiconductor body and the converter layer,
wherein the plurality of openings is at least partially filled with the converter layer, and
wherein the separation layer comprises an electrically insulating material or a transparent electrically conductive material.

30. The component according to claim 29,
wherein bottom surfaces of the openings of the grid are formed by surfaces of the separation layer,
wherein the separation layer has structured regions, and
wherein the converter layer extends throughout the separation layer along vertical direction.

31. The component according to claim 29,
wherein a grid material is a radiation-reflective material, or
wherein a grid material is a non-reflective material that is coated to be radiation-reflective.

32. The component according to claim 29, wherein the separation layer comprises a transparent electrically conductive material.

33. The component according to claim 29,
wherein the component comprises a first separation layer and a second separation layer, wherein a common interface is formed between the separation layers,
wherein the common interface is formed by planar surfaces of the separation layers brought into physical contact, and
wherein the common interface is free of an adhesion promoter material which is different from a material of the first separation layer and different from a material of the second separation layer.

34. The component according to claim 29, wherein the component has a structured contact layer having a plurality of spatially separated partial layers configured for local electrical contacting of different subregions of the semiconductor body.

35. The component according to claim 29,
wherein the semiconductor body has a first semiconductor layer facing the converter layer and a second semiconductor layer facing away from the converter layer,
wherein the active zone is located between the first semiconductor layer and the second semiconductor layer,
wherein the first semiconductor layer is contiguous, and
wherein the component has an internal structure extending throughout the second semiconductor layer and the active zone into the first semiconductor layer.

36. The component according to claim 35, wherein the internal structure has at least one through-via or a plurality of through-vias configured to electrically contact the first semiconductor layer.

37. The component according to claim 36, wherein the internal structure has an insulation layer which laterally surrounds the through-via at least in places, so that the through-via is electrically insulated from the second semiconductor layer and from the active zone by the insulation layer.

38. The component according to claim 35, wherein the internal structure is contiguous such that the second semiconductor layer and the active zone are separated by the internal structure into a plurality of individually contactable subregions of the semiconductor body.

39. The component according to claim 29,
wherein the component has a terminal structure which is arranged between the grid and the semiconductor body and is configured to electrically contact the semiconductor body, and
wherein the terminal structure is directly adjacent to the grid and extends along a vertical direction from the grid into the semiconductor body.

40. The component according to claim 29, wherein the component comprises a transparent encapsulation layer disposed on the converter layer and on surfaces of the grid facing away from the semiconductor body, or at least partially between the converter layer and the semiconductor body.
